(19) United States
(12) Patent Application Publication
(10) Pub. No.: US 2024/0363448 A1
(43) Pub. Date: Oct. 31, 2024

(54) MEASURING SYSTEMS, PROCESSING SYSTEMS, AND RELATED APPARATUS AND METHODS, INCLUDING BAND GAP MATERIALS

(71) Applicant: Applied Materials, Inc., Santa Clara, CA (US)

(72) Inventors: Zhepeng CONG, San Jose, CA (US); Zuoming ZHU, Sunnyvale, CA (US); Ala MORADIAN, Sunnyvale, CA (US); Tao SHENG, Santa Clara, CA (US); Khokan C. PAUL, Cupertino, CA (US); Ashur J. ATANOS, San Jose, CA (US)

(21) Appl. No.: 18/417,347

(22) Filed: Jan. 19, 2024

Related U.S. Application Data
(60) Provisional application No. 63/461,835, filed on Apr. 25, 2023.

(51) Int. Cl. H01L 21/66; G01K 15/00; H01L 21/67

(52) U.S. Cl. CPC H01L 22/12; G01K 15/005; H01L 21/67248

(57) ABSTRACT

Embodiments of the present disclosure relate to measuring systems, processing systems, and related apparatus and methods that include band gap materials for temperature measurement calibration. In one or more embodiments, a measurement system includes a substrate support assembly that includes an inner section and an outer section. The inner section includes a first face, a second face opposing the first face, one or more first support recesses formed in the first face, and one or more openings extending between the one or more first support recesses and the second face. The measurement system includes one or more calibration substrates sized and shaped for positioning at least partially in the one or more first support recesses. The measurement system includes a band edge calibration assembly that includes an energy source and a band edge detector.

### CROSS-REFERENCE TO RELATED APPLICATION

This application claims priority to U.S. provisional patent application Ser. No. 63/461,835, filed Apr. 25, 2023, which is herein incorporated by reference in its entirety.

### BACKGROUND

Embodiments of the present disclosure relate to measuring systems, processing systems, and related apparatus and methods that include band gap materials for temperature measurement calibration.

### DESCRIPTION OF THE RELATED ART

Semiconductor substrates are processed for a wide variety of applications, including the fabrication of integrated devices and microdevices. Precise control over a heating source, allows a substrate to be heated within tolerances. The temperature of the substrate can affect the uniformity of the material deposited on the substrate.

The temperature of the substrate can be measured throughout the deposition process using temperature sensors. Over time, the temperature readings of the temperature sensors can drift due to changes of the conditions of the hardware within the process chamber. Aging of the heating lamps and/or substrate supports (among other factors) can affect the temperature measurements over time, hindering accuracy. Coating of window(s) can also affect temperature measurements, hindering accuracy. Moreover, energy received that is not due to emissivity can affect accuracy of measurements. Calibration methods can involve opening of the process chamber and machine down time. Moreover, it can be difficult and time-consuming to calibrate multiple temperature sensors at different locations.

Therefore, a need exists for improved methods and apparatus for calibrating temperature sensors of systems that include thermal process chambers.

### SUMMARY

Embodiments of the present disclosure relate to measuring systems, processing systems, and related apparatus and methods that include band gap materials for temperature measurement calibration. In one or more embodiments, the band gap materials are different from each other.

In one or more embodiments, a measurement system for measuring temperatures applicable for semiconductor manufacturing includes a substrate support assembly. The substrate support assembly includes an inner section and an outer section. The inner section includes a first face, a second face opposing the first face, one or more first support recesses formed in the first face, and one or more openings extending between the one or more first support recesses and the second face. The outer section is configured to support an outer region of the inner section. The measurement system includes one or more calibration substrates sized and shaped for positioning at least partially in the one or more first support recesses. The measurement system includes a band edge calibration assembly that includes an energy source positioned to emit a first energy, and a band edge detector disposed adjacent to the energy source and positioned to receive the first energy.

In one or more embodiments, a system for processing substrates applicable for semiconductor manufacturing includes a chamber body that includes one or more sidewalls. The one or more sidewalls at least partially define an internal volume. The system includes a lid, a window, one or more heat sources configured to heat the internal volume, and a substrate support assembly disposed in the internal volume. The substrate support assembly includes an inner section and an outer section. The inner section includes a first face, a second face opposing the first face, a plurality of first support recesses formed in the first face, and a plurality of openings extending between the plurality of first support recesses and the second face. The outer section is configured to support an outer region of the inner section. The system includes a band edge calibration assembly that includes an energy source positioned to emit a first energy, and a band edge detector disposed adjacent to the energy source and positioned to receive the first energy.

In one or more embodiments, a method of calibrating measurements applicable for semiconductor manufacturing includes transferring a plurality of calibration substrates into a process chamber. The plurality of calibration substrates are supported on a substrate support section. The method includes irradiating the plurality of calibration substrates using an energy source, measuring a plurality of band edge absorption wavelengths using a band edge detector, and measuring a plurality of temperatures of the calibration substrates using one or more temperature sensors. The method includes determining a plurality of calibration temperatures of the calibration substrates using the band edge absorption wavelengths. The method includes calibrating the one or more temperature sensors by comparing the plurality of temperatures of the calibration substrates and the plurality of calibration temperatures of the calibration substrates. The method includes transferring the calibration substrates supported on the substrate support section out of the process chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic cross-sectional view of a processing system, according to one or more embodiments.

FIG. 2 is a schematic enlarged view of the processing system shown in FIG. 1, according to one or more embodiments.

FIG. 3 is a schematic top view of the inner and outer sections and the one or more calibration substrates shown in FIG. 2, according to one or more embodiments.

FIG. 4 is a schematic sectional view of the measurement assembly used with respect to the process chamber of FIG. 1, according to one or more embodiments.

FIG. 5 is a schematic enlarged view of the processing system shown in FIG. 1, according to one or more embodiments.

FIG. 6 is a schematic top view of the inner and outer sections and the one or more calibration substrates shown in FIG. 5, according to one or more embodiments.

FIG. 7 is a partial schematic cross-sectional view of an in-situ reflectometry system (ISR) that can be used with the measurement assembly, according to one or more embodiments.

FIG. 8 is a schematic flow diagram view of a method of using the measurement assembly of FIG. 1, according to one or more embodiments.

FIG. 9 is a schematic diagram view of a method of calibrating temperature sensors, such as the temperature sensors of FIG. 1, according to one or more embodiments.

FIG. 10 shows the measurement of the intensity of wavelengths over a range of wavelengths, according to one or more embodiments.

FIG. 11 shows a correlated temperature graph, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure relate to measuring systems, processing systems, and related apparatus and methods that include differing band gap materials for temperature measurement calibration.

FIG. 1 is a schematic cross-sectional view of a processing system 100, according to one or more embodiments. The processing system 100 includes a process chamber 101 and a controller 175. The processing system 100 can be configured to conduct epitaxial deposition processes in the process chamber 101.

The process chamber 101 includes a housing structure 102 made of a process resistant material, such as aluminum or stainless steel, for example 316L stainless steel. The housing structure 102 can be at least part of a chamber body. The housing structure 102 encloses various functioning elements of the process chamber 101, such as a quartz chamber 104, which includes an upper quartz window 105 and a lower quartz window 106. The quartz chamber 104 encloses an interior volume 110 (also referred to as process volume). One or more liners 108, 109 can protect the housing structure 102 from reactive chemistry and/or can insulate the quartz chamber 104 from the housing structure 102.

The process chamber 101 includes a substrate support assembly 120. The substrate support assembly 120 includes a susceptor assembly 130. A substrate 50 can be positioned on the susceptor assembly 130 during processing, such as during depositions.

The process chamber 101 can further include upper heat sources 164A and lower heat sources 164B for heating of the substrate 50 and/or the interior volume 110. The heat sources 164A, 164B can be radiant heat sources such as lamps, for example halogen lamps and/or infrared (IR) lamps. In one or more embodiments, the heat sources 164A, 14B are operable to emit IR light and/or ultraviolet light. The present disclosure contemplates that other heat sources may be used (in addition to or in place of the lamps) for the various heat sources described herein. For example, resistive heaters, light emitting diodes (LEDs), and/or lasers may be used for the various heat sources described herein.

The substrate support assembly 120 can include an actuator 119, an outer shaft 121, and inner shaft 122. The actuator 119 is configured to vertically move the inner shaft 122 relative to the outer shaft 121. The actuator 119 is further configured to rotate the inner shaft 122 while the outer shaft 121 remains stationary. The inner shaft 122 is configured to rotate about a central axis C extending in the vertical direction through the center of the inner shaft 122.

The substrate support assembly 120 includes the susceptor assembly 130, a support plate 125, and a plurality of support pins 126, such as three support pins 126 positioned 120 degrees apart from each other a same distance from the central vertical axis C. In one or more embodiments, the support plate 125 and the support pins 126 can be formed of quartz or silicon carbide. The support plate 125 is positioned over (e.g., directly on) the inner shaft 122. The support plate 125 can include a center 125C aligned with the central vertical axis C. The support pins 126 are each positioned over (e.g., directly on) the support plate 125. The susceptor assembly 130 is positioned over (e.g., directly on) the support pins 126.

The susceptor assembly 130 includes an outer section 131 and an inner section 150. The inner section 150 is positioned on and supported by the outer section 131. The inner section 150 can be easily moved (e.g., lifted) from the outer section 131 as described in fuller detail below. In one or more embodiments, the inner section 150 and/or the outer section 131 are formed of an opaque material (such as white quartz, grey quartz, quartz with impregnated particles (such as SiC particles or silicon particles), black quartz, silicon carbide (SiC), and/or graphite coated with SiC). In one or more embodiments, the outer section 131 can have a ring shape. The outer section 131 can be positioned around the inner section 150. The inner section 150 can be positioned on a portion of the outer section 131 as described in further detail below. The process chamber 101 can include a preheat ring 114 that can be positioned around the susceptor assembly 130.

The substrate support assembly 120 includes a first plurality of lift pins 140A and a second plurality of lift pins 140B. One of each plurality of lift pins 140A, 140B is shown in FIG. 1 to simplify the drawing. In one or more embodiments, the first plurality of lift pins 140A and the second plurality of lift pins 140B can be formed of quartz (such as transparent quartz). In one or more embodiments, the first plurality of lift pins 140A includes three lift pins 140A₁₋₃, and the second plurality of lift pins 140B includes three lift pins 140B₁₋₃. The first and second pluralities of lift pins 140A, 140B can include two lift pins of each type or more than three lift pins of each type.

The first plurality of lift pins 140A can be positioned and configured to lift a substrate 50 above the susceptor assembly 130 to allow the substrate 50 to be transferred to and from the interior volume 110 of the process chamber 101. The second plurality of lift pins 140B can be positioned and configured to lift the inner section 150 of the susceptor assembly 130 above the outer section 131 of the susceptor assembly 130 to allow the inner section 150 of the susceptor assembly 130 to be transferred to and from the interior volume 110 of the process chamber 101.

The substrate support assembly 120 can further include three lift pin pads 123. More or less lift pin pads (e.g., two lift pin pads) can be used. Each lift pin pad 123 can be attached to the outer shaft 121. In one or more embodiments, the lift pin pads 123 can be formed of quartz (such as transparent quartz).

The lift pin pads 123 can be positioned 120 degrees apart from each other relative to the central axis C that extends through a center of the outer shaft 121. A first lift pin pad 1231 and a second lift pin pad 1232 are shown in FIG. 1. A third lift pin pad 1233 is not visible in FIG. 1. Each of the lift pin pads 123 is also positioned at a same distance from the central axis C as the distance of each of the lift pins 140A, 140B from the center 125C of the support plate 125. As described in further detail below, the position of the lift pads 123 allows the substrate support assembly 120 to rotate the support plate 125 (1) to a substrate-lifting position (first position) in which each of the first plurality of lift pins 140A₁₋₃ overlies one of the lift pin pads 123 or (2) to an inner susceptor-lifting position (second position) in which each of the second plurality of lift pins 140B₁₋₃ overlies one of the lift pin pads 123. Used herein, “overlies” and “underlies” refer to components that have different vertical positions, but at least partially overlap in horizontal positions along respective XY planes thereof.

When the support plate 125 is in the substrate-lifting position, the actuator 119 can lower the inner shaft 122 causing the lift pins 140A to contact the lift pin pads 123 and push the substrate 50 above the inner section 150 of the susceptor assembly 130 using movable lift pin caps as described in further detail below. When the actuator 119 lowers the inner shaft 122 to cause the first plurality of lift pins 140A to contact the lift pin pads 123 with the support plate 125 in the substrate-lifting position, the second plurality of lift pins 140B do not contact any lift pin pads 123 and instead move closer to the lower quartz window 106.

When the support plate 125 is in the inner susceptor-lifting position, the actuator 119 can lower the inner shaft 122 causing the lift pins 140B to contact the lift pin pads 123 and push the inner section 150 of the susceptor assembly 130 above the outer section 131 as described in further detail below. When the actuator 119 lowers the inner shaft 122 to cause the second plurality of lift pins 140B to contact the lift pin pads 123 with the support plate 125 in the inner susceptor-lifting position, the first plurality of lift pins 140A do not contact any lift pin pads 123 and instead move closer to the lower quartz window 106.

In one or more embodiments, one or more of the lift pin pads 123 can include a sensor (e.g., a proximity sensor) connected to the controller 175 to detect when one of the lift pins 140A, 140B overlies lift pin pad 123. The controller 175 can use the feedback from the sensor to stop the rotation of the support plate 125 by the actuator 119. This can enable the controller to align the first plurality of lift pins 140A to overlie the lift pin pads 123 for lifting the substrate 50 or to align the first plurality of lift pins 140B to overlie the lift pin pads 123 to lift the inner section 150.

In one or more embodiments, the process chamber 101 can include an encoder 180. In one or more embodiments, the encoder can be attached to an outside of the inner shaft 122, such as near a bottom of the inner shaft 122. The encoder 180 can be used to control the angular amount (e.g., 60 degrees, 90 degrees, 180 degrees, etc.) from a home position that the susceptor assembly 130 has rotated. Determining and controlling this angular rotation of the inner shaft 122 enables the susceptor assembly 130 to be rotated to any angle from a home position, which provides the capability for the susceptor assembly 130 and substrate 50 to be rotated to angular positions, such as a first position aligning the lift pin pads 123 with the first plurality of lift pins 140A and a second position aligning the lift pin pads 123 with the second plurality of lift pins 140B.

The processing system 100 also includes the controller 175 for controlling processes performed by the processing system 100. The controller 175 can be any type of controller used in an industrial setting, such as a programmable logic controller (PLC). The controller 175 includes a processor 177, a memory 176, and input/output (I/O) circuits 178. The controller 175 can include one or more of the following components, such as one or more power supplies, clocks, communication components (e.g., network interface card), and user interfaces typically found in controllers for semiconductor equipment.

The memory 176 can include a non-transitory memory (e.g., a non-transitory computer readable medium). The non-transitory memory can be used to store the programs and settings described below. The memory 176 can include one or more readily available types of memory, such as read only memory (ROM) (e.g., electrically erasable programmable read-only memory (EEPROM)), flash memory (e.g., flash drive), floppy disk, hard disk, random access memory (RAM) (e.g., non-volatile random access memory (NVRAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), or any other form of digital storage, local or remote.

The processor 177 is configured to execute various programs stored in the memory 176, such as epitaxial deposition processes and processes for transferring substrates and susceptors into and out of the interior volume 110. During execution of these programs, the controller 175 can communicate to I/O devices through the I/O circuits 178. For example, during execution of these programs and communication through the I/O circuits 178, the controller 175 can control outputs, such as the rotational position of susceptor assembly 130 relative to the lift pin pads 123 and the vertical position of the susceptor assembly 130 through use of the actuator 119. The memory 176 can further include various operational settings used to control the processing system 100.

The controller 175 is configured to conduct any of the operations described herein. In one or more embodiments, the instructions stored on the memory 176, when executed, cause one or more of operations of method 800 and/or the method 900 (described below) to be conducted in relation to the processing chamber 101. The various operations described herein (such as the operations of the method 800 and/or the method 900) can be conducted automatically using the controller 175, or can be conducted automatically or manually with certain operations conducted by a user.

The processing system 100 includes a measurement assembly 270, according to one or more embodiments. The controller 175 can control the measurement assembly 270, and conduct calibration of one or more temperature sensors 272, 278. In one or more embodiments, the one or more temperature sensors 272, 278 respectively include a pyrometer that includes a silicon sensor. The measurement assembly 270 facilitates accurate measurement of the temperature of the substrate 50. The measurement assembly 270 includes an energy source 274 (e.g., a light source) and a band edge detector 276. An upper temperature sensor 272, the energy source 274, and the band edge detector 276 are disposed above the substrate 50. A lower temperature sensor 278 is disposed below the substrate 50. The energy source 274 and the band edge detector 276 are part of a band edge calibration assembly of the measurement assembly 270.

The energy source 274 is positioned to emit a first energy, and the band edge detector 276 is disposed adjacent to the energy source 274 and positioned to receive the first energy.

The energy source 274 is a laser light source with a controlled intensity and wavelength range. In one or more embodiments, a broad band light source is used. The energy source 274 may be a diode laser or an optical cable. When the energy source 274 is an optical cable, the optical cable is connected to an independent energy source (e.g., light source), which may be disposed near the process chamber 101. The energy source 274 may be a bundle of lasers or optical cables, such that a plurality of beams (e.g., light beams) are focused into a first calibration beam 286 (e.g., calibration light beam). In one or more embodiments, the energy source 274 can emit radiation at a varying wavelength range. The varying wavelength range allows the energy source 274 to emit wavelengths which would be within about 200 nm of the expected absorption edge wavelength of a calibration substrate (described below). The use of a varying wavelength range eliminates noise which may be caused by the use of a wider wavelength spectrum and allows for an increase in the strength of emission of the narrower range from the energy source 274 to increase the signal strength received by the band edge detector 276. In one or more embodiments, one or more of the heat sources 164A are used as the energy source 274. In one or more embodiments, the energy source 274 may be classified as a radiation source, such as a thermal radiation source or a broad band radiation source. The radiation source may be a laser diode or an optical assembly. The optical assembly may include a laser, a lamp, and/or a bulb, and/or a plurality of lenses, mirrors, or a combination of lenses and mirrors.

The band edge detector 276 measures the intensity of different wavelengths of energy (e.g., light) within a second calibration beam 284 (e.g., light beam), which is reflected off the calibration substrate 350. The band edge detector 276 is configured to find a wavelength at which the calibration substrate 350 transitions from absorbing a wavelength of radiation to reflecting nearly all of a wavelength of radiation. The band edge detector 276 may include several optical components disposed therein in order to separate and measure the second calibration beam 284. In one or more embodiments, the band edge detector 276 is a scanning band edge detector and scans through a range of wavelengths to determine the transition wavelength at which the calibration substrate (which is in place of the substrate 50) transitions from absorbing to reflecting radiation. In one or more embodiments, the band edge detector 276 measures the intensity of wavelengths of energy (e.g., light) transmitted through a calibration substrate (described below) from below the calibration substrate (such as through an opening 255 and then through the calibration substrate 260 described below). The intensity of wavelengths of the radiation transmitted through the calibration substrate may be measured by the band edge detector 276. The band edge detector 276 then determines a transition wavelength at which the calibration substrate 350 transitions from absorbing wavelengths to transmitting wavelengths. An optional filter may be placed between the band edge detector 276 and the inner and outer sections 130, 250 (described below) and configured to filter out radiation emitted by the heat sources 164A, 164B.

FIG. 2 is a schematic enlarged view of the processing system 100 shown in FIG. 1, according to one or more embodiments. In the implementation shown in FIG. 2, the inner section 150 has been replaced with an inner section 250.

The inner section 250 includes an outer shoulder 251, a first face 252, a second face 253 opposing the first face 252, one or more first support recesses 254 formed in the first face 252, and one or more openings 255 extending between the one or more first support recesses 254 and the second face 253. The outer section 131 is configured to support an outer region of the inner section 250. One or more calibration substrates 260 (one is shown in FIG. 2) are positioned at least partially in the one or more first support recesses 254.

FIG. 3 is a schematic top view of the inner and outer sections 250, 130 and the one or more calibration substrates 260 shown in FIG. 2, according to one or more embodiments. In the implementation shown in FIGS. 2 and 3, the inner section 250 supports a single calibration substrate 260 (a first calibration substrate 260A) for calibration. The inner section 250 and the first calibration substrate 260A can be removed from the process chamber 101, and one or more additional substrates 260B-260E (four are shown) can be sequentially transferred into the process chamber 101 for calibration and transferred out of the process chamber 101. The one or more additional calibration substrates 260B-260E can be transferred into and out of the process chamber 101 on the same inner section 250 or on one or more additional inner sections (which can be similar to the inner section 250 with respect to one or more aspects, features, components, operations, and/or properties). When not in the process chamber 101, the calibration substrates 260A-260E can be stored at a location (such as on a cassette) exterior to the process chamber 101, such as in a transfer chamber and/or in a load lock chamber.

At least two of the calibration substrates 260A-260E have different band gap materials. In one or more embodiments, the lower temperature sensor 278 irradiates the inner section 250 at approximately a location 261.

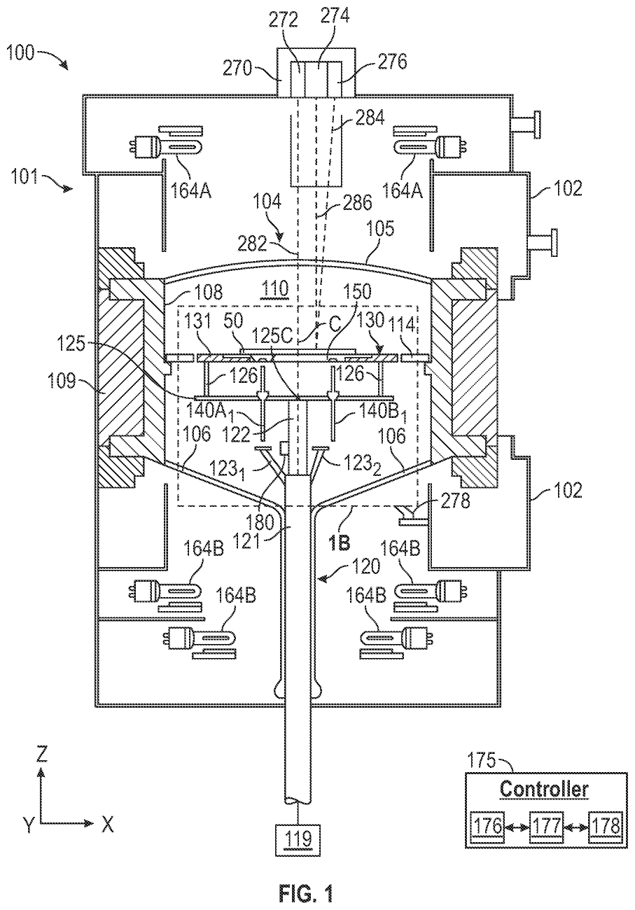

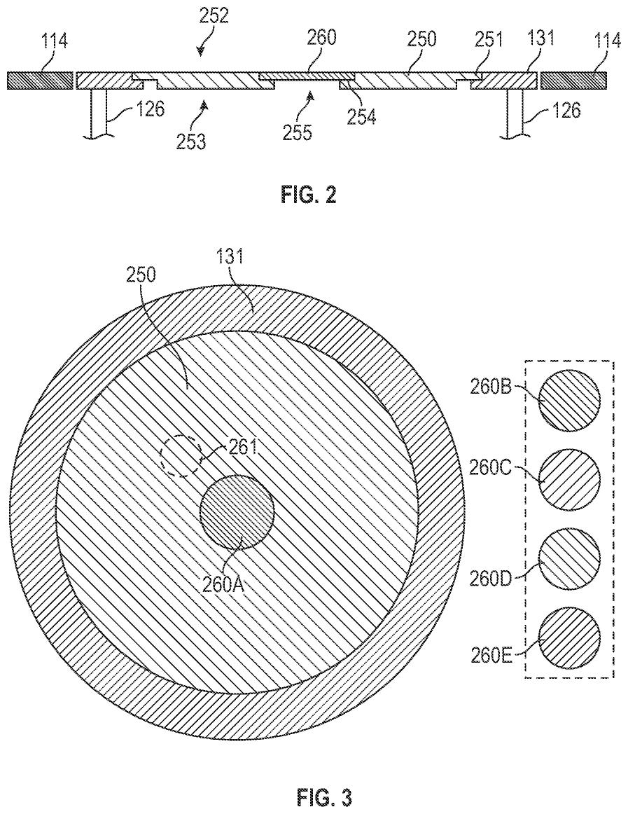

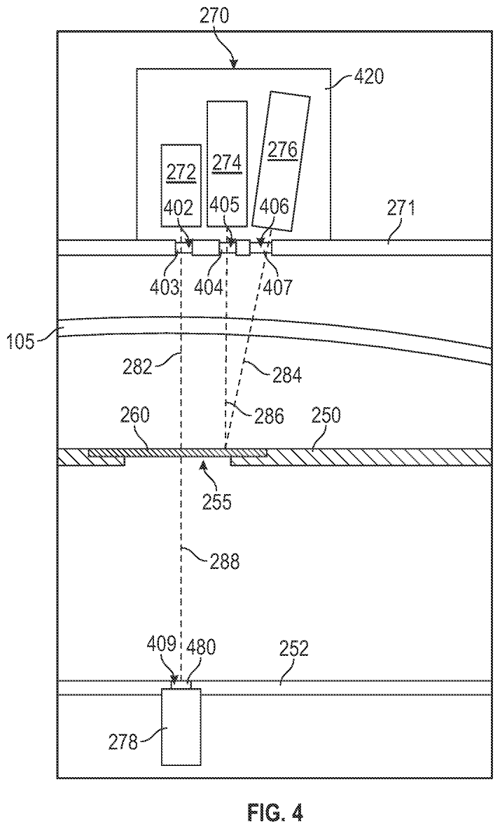

FIG. 4 is a schematic sectional view of the measurement assembly 270 used with respect to the process chamber 101 of FIG. 1, according to one or more embodiments. In addition to the components described with regard to FIG. 1, the measurement assembly 270 of FIG. 4 includes a first window 403, a second window 408, a third window 404, a fourth window 407, and a cover 420.

The first window 403 is disposed within a first opening 402. The first window 403 is disposed between the upper temperature sensor 272 and the upper window 105. The first window 403 is disposed between the upper temperature sensor 272 and the calibration substrate 260A. The first window 403 is a quartz window and allows for radiation from within the process chamber 101 to pass therethrough. The first window 403 may filter radiation emitted by the calibration substrate 260A to allow wavelengths which the upper temperature sensor 272 measures while filtering other wavelengths. The radiation traveling along the first measurement radiation path 282 travels between a top side of the calibration substrate 260A and the upper temperature sensor 272. The first measurement radiation path 282 intersects both the upper window 105 and the first window 403. In one or more embodiments, the first measurement radiation path 282 may intersect the top side of the calibration substrate 260A at any radial position along the calibration substrate 260A. In one or more embodiments, the first measurement radiation path 282 intersects the top side 358 of the calibration substrate 260A at a specific location, such as either less than 15 mm from the center of the calibration substrate, such as less than 10 mm from the center of the calibration substrate, such as less than 5 mm from the center of the calibration substrate or the first measurement radiation path 282 intersects the top side of the calibration substrate 260A at a radius of about 110 mm to about 130 mm, such as about 115 mm to about 125 mm, such as about 120 mm.

The second window 408 is disposed within a second opening 409. The second window 408 is disposed between the lower temperature sensor 278 and the lower window 106. Therefore, the second window 408 is disposed between the lower temperature sensor 278 and the calibration substrate 260A. In the implementation shown in FIG. 4, the lower temperature sensor 278 is aligned approximately below a center of the calibration substrate 260A. The second window 408 is a quartz window and allows for radiation from within the process chamber 101 to pass there through. The second window 408 may filter radiation emitted by the calibration substrate 260A to allow wavelengths which the lower temperature sensor 278 measures while filtering other wavelengths. The radiation traveling along the second measurement radiation path 288 travels between the bottom side of the calibration substrate 260A and the lower temperature sensor 278. The second measurement radiation path 288 intersects both the lower window 106 and the second window 408. In one or more embodiments, the second measurement radiation path 288 may intersect the bottom side of the calibration substrate 260A or the inner section 250 at any radial position along the calibration substrate 260A. In one or more embodiments, the second measurement radiation path 288 intersects the bottom side of the calibration substrate 260A at a specific radial position, such as a radial position directly below the calibration substrate 260A and either less than 15 mm from the center of the calibration substrate, such as less than 10 mm from the center of the calibration substrate, such as less than 5 mm from the center of the calibration substrate or the second measurement radiation path 288 intersects the bottom side of the calibration substrate 260A at a radial position directly below the calibration substrate 260A at a radius of about 110 mm to about 130 mm, such as about 115 mm to about 125 mm, such as about 120 mm.

The third window 404 is disposed within a third opening 405. The third window 404 is disposed between the energy source 274 and the upper window 105. Therefore, the third window 404 is disposed between the energy source 274 and the calibration substrate 260A. The third window 404 allows energy (e.g., light) emitted by the energy source 274 to pass there through. The energy emitted by the energy source 274 and traveling along the first calibration beam 286 is disposed between the energy source 274 and the top side of the calibration substrate 260A. The first calibration beam 286 passes through both of the upper window 105 and the third window 404. The first calibration beam 286 may intersect the top side of the calibration substrate 260A at any radial position along the calibration substrate 260A. In one or more embodiments, the first calibration beam 286 intersects the top side of the calibration substrate 260A either less than 15 mm from the center of the calibration substrate, such as less than 10 mm from the center of the calibration substrate, such as less than 5 mm from the center of the calibration substrate or the first calibration beam 286 intersects the top side of the calibration substrate 260A at a radius of about 110 mm to about 130 mm, such as about 115 mm to about 125 mm, such as about 120 mm.

The first calibration beam 286 intersects the top side of the calibration substrate 260A within less than 5 mm, such as less than 2 mm, such as less than 1 mm from the location in which the first measurement radiation path 282 intersects the radiation path. In one or more embodiments, the first calibration beam 286 intersects the top side of the calibration substrate 260A at the same radial position as the first measurement radiation path 282. Measuring the calibration substrate 260A at the same location can allow for a direct comparison between temperature measurements and reduce error when compared to measurements made at different radial distances from the center of the calibration substrate 260A.

The fourth window 407 is disposed within a fourth opening 406 formed through a chamber lid 271. The fourth window 407 is disposed between the band edge detector 276 and the upper window 105. The fourth window 407 is disposed between the band edge detector 276 and the calibration substrate 260A.

The energy (e.g., light) received by the band edge detector 276 and traveling along the second calibration beam 284 is disposed between the band edge detector 276 and the top side of the calibration substrate 260A. The second calibration beam 284 passes through both of the upper window 105 and the fourth window 407. The second calibration beam 284 intersects the top side of the calibration substrate 260A at the same location as the first calibration beam 286. The second calibration beam 284 is a reflection of the first calibration beam 286 off the top side of the calibration substrate 260A. The second calibration beam 284 is altered by intersecting the calibration substrate 260A and has a reduced wavelength range that is measured by the band edge detector 276.

The cover 420 is disposed above the chamber lid 271 and surrounds the upper temperature sensor 272, the energy source 274, and the band edge detector 276. The cover 420 may be disposed around each of the upper temperature sensor 272, the energy source 274, and the band edge detector 276 individually, such that there are a plurality of covers 420. The cover 420 may serve as a support to hold each of the upper temperature sensor 272, the energy source 274, and the band edge detector 276 in place. The cover 420 facilitates reducing or preventing radiant energy from escaping the process chamber 101 and interfering with other equipment.

The temperature of a portion of the calibration substrate 260A and/or the inner section 250 is measured using the upper temperature sensor 272. The temperature of a portion of the calibration substrate 260A and/or the inner section 250 is measured using the lower temperature sensor 278 is a temperature of a bottom surface disposed opposite the location at which the temperature is measured by the upper temperature sensor 272.

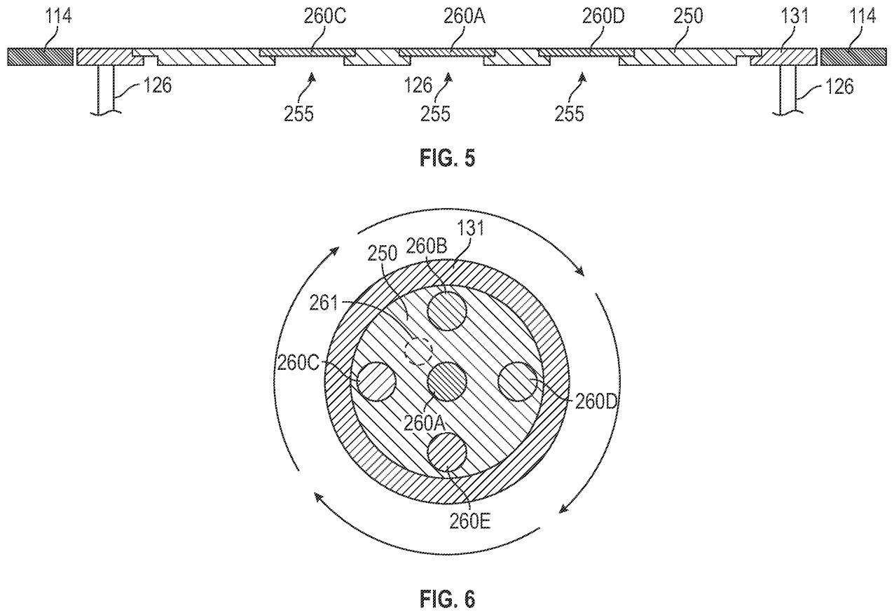

FIG. 5 is a schematic enlarged view of the processing system 100 shown in FIG. 1, according to one or more embodiments.

FIG. 6 is a schematic top view of the inner and outer sections 250, 130 and the one or more calibration substrates 260A-260E shown in FIG. 5, according to one or more embodiments.

In the implementation shown in FIGS. 5 and 6, the inner section 250 includes a plurality of first support recesses 254 and a plurality of openings 255, and the inner section 250 supports the plurality of calibration substrates 260A-260E (which includes an inner calibration substrate 260A and one or more outer calibration substrates 260B-260E positioned outwardly of the inner calibration substrate 260A and along a circumferential pattern).

In one or more embodiments, a first calibration substrate 260A has a first band gap material, a second calibration substrate 260B has a second band gap material, a third calibration substrate 260C has a third band gap material, a fourth calibration substrate 260D has a fourth band gap material, and a fifth calibration substrate 260E has a fifth band gap material. In one or more embodiments, the first band gap material includes a doped silicon, and the doped silicon is P+++ silicon or P− silicon.

In one or more embodiments, the second band gap material includes indium phosphide (InP), the third band gap material includes germanium nitride (GeN), the fourth band gap material includes a first silicon carbide (SiC) having a first atomic structure, and/or the fifth band gap material includes a second SiC having a second atomic structure. In one or more embodiments, the first atomic structure of the first SiC is 3C, and the second atomic structure of the second SiC is 4H or 6H.

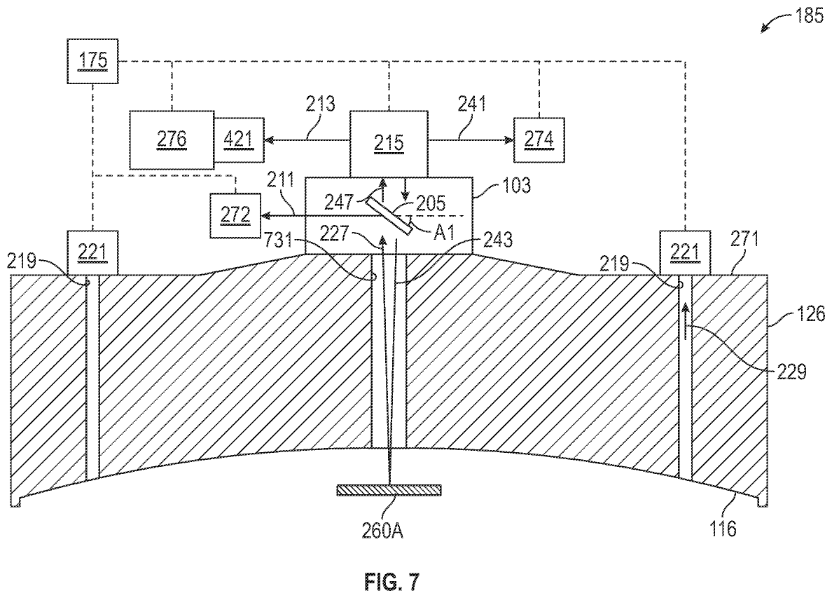

FIG. 7 is a partial schematic cross-sectional view of an in-situ reflectometry system (ISR) 185 that can be used with the measurement assembly 270, according to one or more embodiments. The present disclosure contemplates that other configurations may be used for the measurement assembly 270, for example other than reflectometers. For example, any other type of optical spectrometer(s) configured to detect (e.g., scan) a band edge range for a temperature range may be used. The ISR System 185 includes the energy source 274, a collimator 215, the band edge detector 276, the upper temperature sensor 272, one or more sensor assemblies 221 (two are shown), and a dichroic mirror 205 coupled to or disposed above the chamber lid 271. The ISR System 185 facilitates measurement of one or more properties of the substrate 50 (and/or a thin film disposed thereon). Example properties include temperature, thin film growth rate, thickness of a thin film, thin film optical properties and/or in-film Ge concentration.

The energy source 274 is configured to generate energy 241 (e.g., radiation, such as light). For example, the energy source 274 could be a flash lamp, capable of producing full spectrum or partial spectrum light. In one or more embodiments, the spectrum of light generated has a wavelength between about 200 nm to about 4 micrometers, such as 200 nm to about 800 nm and/or 3 micrometers to 4 micrometers. Full spectrum light allows for a wide range of light signals for analysis, however in one or more embodiments a light source may be limited to a specific wave length of light or specific range of light wave lengths to accomplish the analysis. The energy source 274 may be controlled by the controller 175. The energy source 274 is in optical communication with a collimator 215, and directs energy 241 to the collimator 215 upon instruction of the controller 175. Optical communication includes connection by a fiber optic cable, and other modes of light transmission are contemplated. The travel path of the energy from the energy source 274 may be referred to as a propagation path. The collimated energy 243 (e.g., radiation, such as light) leaves the collimator 215, and travels through a passage 731. In one or more embodiments, the passage 731 includes a light pipe. The passage 731 can be a made of any material capable of transmitting light of predetermined wavelengths, for example, sapphire. The passage 731 directs the collimated energy 243 to the surface of the substrate 50 (or a thin film thereon) or the surface of the calibration substrate 260A to facilitate measurement of one or more properties of the substrate 50 (or a thin film thereon) or one or more properties (such as the transition wavelength) of the calibration substrate 260A.

The collimated energy 243 is reflected off the target measurement surface, such as the calibration substrate 260A, and is reflected back as reflected energy 227. The reflected energy 227 travels back through the passage 731. The reflected energy 227 leaves the passage 731 and travels to the dichroic mirror 205 aligned with the passage 731 along the travel path of the reflected energy 227. In one or more embodiments, the dichroic mirror 205 includes a transparent material with a dielectric coating. The dielectric coating may include, but is not limited to, magnesium fluoride, tantalum pentoxide, and/or titanium dioxide. The dichroic mirror 205 reflects certain wavelengths of energy (e.g., light) away to the upper temperature sensor 272, but allows other specifically selected wavelengths to pass through to the collimator 215. A wavelength range directed to the band edge detector 276 through the collimator 215 may be between about, 100 nm and about 1000 nm, such as within a range of 200 nm and 800 nm, such as within a range of 200 nm and 400 nm, and such as within a range of 400 nm and 800 nm. Other wavelengths are contemplated. The dichroic mirror 205 facilitates multiple light based sensors to be used by directing light of a first desired range of to one sensor (such as the band edge detector 276) with the remaining light wavelengths being sent to at least another sensor (such as the upper temperature sensor 272). Thus, use of optical spectrometer(s) and/or the ISR system 185 facilitates a compact measurement system, allowing more sensors to be included in a smaller footprint. The dichroic mirror 205 is arranged, or oriented, at an angle of incidence A1 between about, 30° and about 60°, such as within a range of 35° and 55°, with a plane near orthogonal to a longitudinal axis of the passage 731. However, other angles of incidence are contemplated.

As shown in FIG. 7, light reflected from the dichroic mirror 205 is transmitted to the upper temperature sensor 272 along an energy path 211 (e.g., a light path). In one or more embodiments, light wavelengths between about 1.0 μm and about 6.0 μm, such as between about 3.0 μm and about 4.0 μm, travel along the energy path 211 to the upper temperature sensor 207. As noted above, properties of the dichroic mirror 205 are selected to transmit or reflect light in specified wavelength ranges. Energy 247 (e.g., light) allowed to pass through the dichroic mirror 205 is collimated by the collimator 215. The collimated energy 213 is directed to the band edge detector 276. In one or more embodiments, the band edge detector 276 includes an optical spectrometer, a spectrograph configured to measure wavelength-resolved intensity. The band edge detector 276 can include a grating, an optical lens, a filter 421 and/or a linear-array photodiode detector. The filter 421 can be a short pass filter to limit the noise from a heat source (such as the heat sources 164A, 164B), or a dielectric filter. A dielectric filter includes any thin film based filters than can reduce or prevent specific wavelength of light from passing therethrough. While the filter 421 is described as part of the band edge detector 276, it is contemplated that the filter can be located in other locations. For example, the filter 421 can be part of the dichroic mirror 205. The filter 421 is configured to allow light of a specified wavelength to pass therethrough, while reducing or preventing passing or other wavelengths. In one or more embodiments, the filter 421 allows light of wavelengths below 550 nm to pass therethrough (while filtering other wavelengths) to mitigate light signal noise from heat sources of the process chamber, thus improving measurement accuracy. It is contemplated that the filter 421 can be placed in any light path that includes the light reflected off the substrate 50 (e.g., reflected energy 227 to the band edge detector 276, reflected energy 247 from dichroic mirror 205, and/or collimated energy 243). In one or more embodiments, the filter 421 is an integral component of the band edge detector 276. In one or more embodiments, the filter 421 is a standalone component from the band edge detector 276. In one or more embodiments, the filter 421 is not included in the path. It is to be noted that while one or more embodiments described herein may include a filter 421 and/or a dichroic mirror 205, both the filter 421 and the mirror 205 are optional and may be excluded from any embodiment or implementation described herein.

An optical spectrometer system and/or the ISR system 185 may optionally include the one or more second sensor assemblies 221 positioned outwardly of the upper temperature sensor 272. The sensor assemblies 221 respectively are configured to be in line (e.g., vertically and/or optically aligned) with an outer passage 219. The sensor assemblies 221 respectively are a spectrometer or a channel of a multi-channel spectrometer configured to measure a property, such as a transition wavelength that indicates a band gap edge. The outer passages 219 extend between a bottom surface and an upper surface of the chamber lid 271. The outer passages 219 may be sealed at upper and lower ends thereof by a material capable of transmitting energy 229 (e.g., light), such as quartz or sapphire. In one or more embodiments, each outer passage 219 includes a fiber optic cable disposed thereon.

In one or more embodiments, the sensor assemblies 221 respectively include an energy source (similar to the energy source 274), a collimator (similar to the collimator 215), a housing (similar to a housing 103), a mirror (similar to the dichroic mirror 205), a filter (similar to the filter 421), a band gap detector (similar to the band edge detector 276), and/or a temperature sensor (similar to the upper temperature sensor 272).

In one or more embodiments, the sensor assemblies are respectively configured to read a reference material of each calibration substrate 260A-260E for use as a temperature reference. For example, the reference material can have known properties.

For each sensor assembly, the reflected signal travels back to the dichroic mirror and is split into multiple paths (e.g., propagation sub-paths). A first propagation sub-path directs reflected light to the respective temperature sensor 272, while a second propagation sub-path directs reflected light to the collimator 215 and then to the band edge detector 276. The light intensity collected by the band edge detector 276 is analyzed for true reflectance, which is compared with models, for example (Fresnel equations) using nonlinear fitting equations or other empirically derived equations to determine an adjusted temperature reading for the temperature sensor 272.

In one or more embodiments, models are empirically derived by obtaining absorption/reflectance data for light at predetermined wavelengths for various materials of various calibration substrates. The data may be collected at conditions which approximate those of a predetermined recipe for processing future substrates, such as a process recipe at which the model will be used. The data is then fit to an equation, such as a non-linear equation. Light received by the band edge detector 276 is analyzed for intensity (e.g., true reflectance of light reflected from the measured calibration substrate) and fit to the empirically derived equation to determine the adjusted temperature reading. Stated otherwise, the amount of light reflected from the calibration substrate surface changes depending upon the material of the calibration substrate, and the amount of light can be compared to known data to determine the adjusted temperature reading. This data and/or equations may also take into account other optical properties, such as refractive index and/or extinction coefficient, to facilitate measurement accuracy.

The band edge detector 276 can measure the band edge wavelength of the inner calibration substrate 260A shown in FIG. 6, the band edge detector of the left-side sensor assembly 221 can measure the band edge wavelength of the outer calibration substrate 260C shown in FIG. 6, and the band edge detector of the right-side sensor assembly 221 can measure the band edge wavelength of the outer calibration substrate 260D shown in FIG. 6. The inner section 250 and outer section 131 can be rotationally stepped to align the outer calibration substrate 260B and the outer calibration substrate 260E under the sensor assemblies 221 so that band edge wavelengths of the outer calibration substrates 260B, 260E can be measured to calibrate temperature sensors. The present disclosure contemplates that a plurality of band edge wavelength measurements (for the same calibration substrate or across a variety of calibration substrates) can be averaged for an adjusted temperature (e.g., a correction value) to be applied to temperature measurements taken using a temperature sensor.

The present disclosure contemplates that a plurality of calibration substrates having different band gap materials are used to calibrate a temperature sensor (such as a multi-channel temperature sensor) that measures energy (e.g., light) at a plurality of different wavelengths (such as 1.5 microns, 2.7 microns, 3.4 microns, and 5.0 microns). In one or more embodiments, the number of calibration substrates and the number of different band gap materials used for the calibration substrates are equal to the number of different wavelengths used for the temperature sensor.

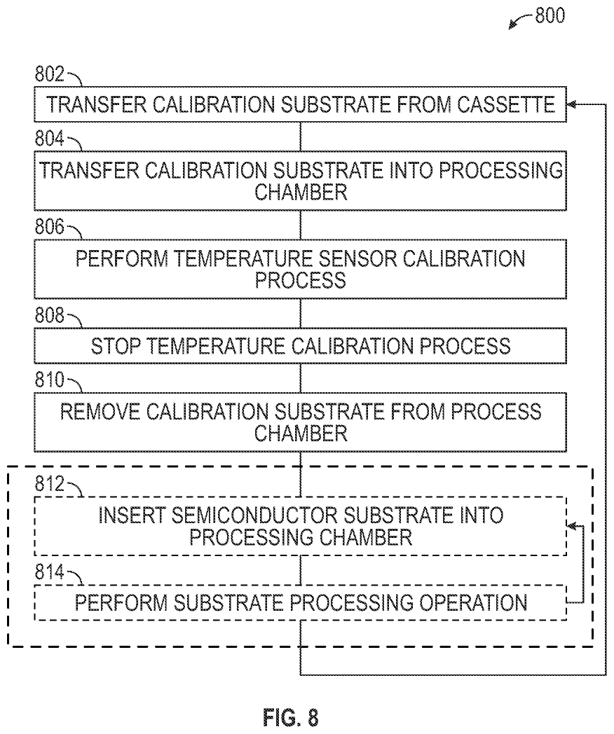

FIG. 8 is a schematic flow diagram view of a method 800 of using the measurement assembly 270 of FIG. 1, according to one or more embodiments. The method 800 includes a first operation 802, a second operation 804, a third operation 806, a fourth operation 808, a fifth operation 810, an optional sixth operation 812, and an optional seventh operation 814. In one or more embodiments, the operations 802, 804, 806, 808, 810, 812, and 814 are performed sequentially as shown in FIG. 8 and described herein.

The method 800 includes a first operation 802 of transferring one or more calibration substrates, such as one or more of the calibration substrates 260A-260E from a cassette. One or more of the calibration substrates 260A-260E can be stored within the cassette between each calibration of the temperature sensors 272, 278.

During the second operation 804, a transfer robot transfers the calibration substrate(s) into the processing chamber, such as the processing chamber 101. The calibration substrate(s) are supported, for example, by the inner section 250 carried by the transfer robot. The inner section 250 is placed onto the outer section 131 and the transfer robot is retracted from the process chamber 101.

During the third operation 806, a calibration process is performed. The calibration process includes using one or more (such as one, at least two, or all) of the calibration substrate(s) and the measurement assembly 270. The calibration process of the third operation 806 is described in greater detail with reference to the method 900 of calibrating the temperature sensors.

After the third operation 806, the temperature calibration process is stopped in a fourth operation 808. Stopping the temperature calibration process includes stopping the flow of any process gases introduced into the process chamber (if used), stopping of any heating of the calibration substrate(s), and ceasing of the measurement of the temperature(s) of the calibration substrate(s).

After the temperature calibration process is ceased, the calibration substrate(s) are removed from the process chamber in a fifth operation 810. The calibration substrate(s) are removed by the transfer robot through a loading port. The calibration substrate(s) are inserted back into the cassette subsequent to being removed from the process chamber 101.

After removal of the calibration substrate(s) from the process chamber, a semiconductor substrate may be transferred into the process chamber during the optional sixth operation 812. The semiconductor substrate may be similar to the substrate 50 (FIG. 1). The semiconductor substrate may have partially formed semiconductor devices disposed thereon. The semiconductor substrate is transferred into the process chamber by the transfer robot and may have been stored within the cassette during the temperature calibration process or may have been stored in a separate process chamber.

Subsequent to the optional sixth operation 812 of transferring a semiconductor substrate into the process chamber, a substrate processing operation is performed during the optional seventh operation 814. The substrate processing operation may include a deposition process on the top surface of the substrate. The substrate processing operation may further include heating the substrate, introducing at least one process gas, introducing a purge gas, and evacuating the process and purge gases. A plurality of substrates can be processed during the substrate processing operation.

The optional sixth and seventh operations 812, 814 can be repeated so that between each calibration process multiple substrates are processed. The optional sixth and seventh operations 812, 814 may be repeated, such that more than 50 substrates are processed within the processing chamber between each calibration process. In one or more embodiments, the calibration process is performed once every several days and several hundred substrates are processed within the processing chamber between each calibration process. The sixth and seventh operations 812, 814 are optional. In one or more embodiments, the sixth and seventh operations 812, 814 are omitted from the method 800.

The method 800 is repeated automatically after a preset amount of substrates have been processed within the processing chamber or after the processing chamber has reached a preset run time. The method 800 is automated and programmed into a controller, such as the controller 175. The method 800 may not use human intervention and can be completed without disassembly of the process chambers. The calibration of the temperature sensors using the method 800 can involve minimum downtime of the system by pausing processing operations for the length of time it takes to perform operations 804, 806, 808, and 810 and re-initiating the processing operations after the length of time has elapsed.

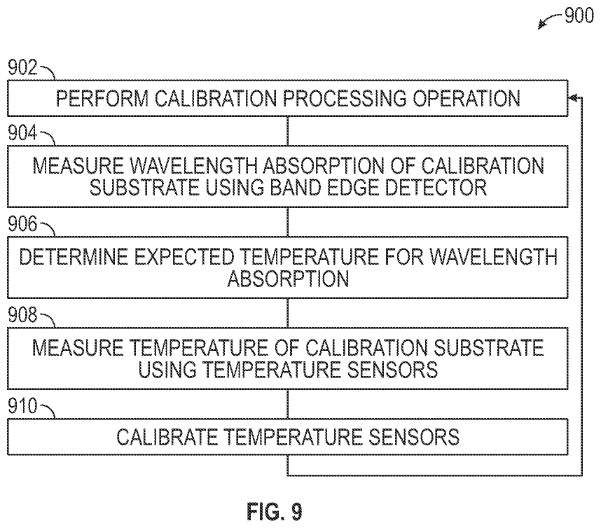

FIG. 9 is a schematic diagram view of a method 900 of calibrating temperature sensors, such as the temperature sensors 272, 278 of FIG. 1, according to one or more embodiments. The method 900 can be part of the third operation 806 of the method 800 described herein. Calibrating the temperature sensors includes a first operation 902, a second operation 904, a third operation 906, a fourth operation 908, and a fifth operation 910. The operations 902, 904, 906, 908, 910 described with regard to the method 900 can be performed subsequently as shown in FIG. 9 and described herein. Other sequences are contemplated. For example, operations 904 and/or 906 can be performed after or simultaneously with operation 908.

The first operation 902 includes performing a calibration processing operation. The calibration processing operation may be similar to the substrate processing operation 814 performed on the substrate. The calibration processing operation can include heating one or more (such as one, at least two, or each) of the calibration substrate(s), introducing a process gas, introducing a purge gas, and evacuating the process and purge gases. The process gas may be different from the process gas used in the substrate processing operation of the seventh operation 814 of the method 800. A process gas may be a carrier gas, such as an H₂ gas. The carrier gas assists in matching process conditions with those found in the substrate processing operation 814 (which is optional to the method 800). The carrier gas assists in matching the pressure and gas flow which would be found during the substrate processing operation 814. The process gas may not include reactant gases or deposition/etch gases, which may alter the surface(s) of the calibration substrate(s). The process chamber and calibration substrate(s) may be heated using the heat sources 164A, 164B and/or a susceptor heater. The heating of the process chamber and the calibration substrate(s) is performed gradually and the temperature increases over time.

The second operation 904 includes measuring a wavelength of absorption (e.g., a band edge absorption wavelength) of one or more (such as one, at least two, or each) of of the calibration substrate(s) using the band edge detector 276 (FIGS. 1 and 4). During the second operation 904 a first calibration beam 286 is emitted by the energy source 274 or one of the heat sources 164A, 164B. When the first calibration beam 286 strikes the top side of the calibration substrate at a first location, a first wavelength range of the first calibration beam 286 is absorbed by the calibration substrate while a second wavelength range of the first calibration beam 286 is reflected as the second calibration beam 284. The second calibration beam 284 enters the band edge detector 276. The band edge detector 276 measures the intensity of a variety of wavelengths within the wavelength spectrum of the second calibration beam 284. The band edge detector 276 maps the intensity of the wavelength measurements over the wavelength range measured by the band edge detector 276. A broad band light source (such as the energy source 274) or one or more heat sources 164A, 164B are used to form the first calibration beam 286. The energy source 274 may be beneficially used in order to improve the accuracy of the measurement. The energy source 274 may emit a precise range of wavelengths at a set intensity and direction. This makes the energy source 274 highly adjustable and may provide for improved measurement precision. The heat sources 164A, 164B may be used to reduce the number of components disposed on a lid of the process chamber. The heat sources 164A, 164B emit a range of light which may be similar to the range emitted by the energy source 274. The heat sources 164A, 164B have a controlled intensity. The heat sources 164A, 164B may be used to emit light which is absorbed and reflected by the calibration substrate(s).

In one or more embodiments, radiation is transmitted through the calibration substrate(s) and measured by the band edge detector 276 on the opposite side of the calibration substrate(s) from the heat sources 164A, 164B. This may occur when the outer section 131 and/or the inner section 250 are transparent to the light emitted by the light source at a wavelength detected by the band edge detector 276 or when the inner section 250 and/or outer section 131 emits radiation after heating.

The band edge detector 276 may measure the intensity of wavelengths between about 250 nanometers (nm) to about 1350 nm, such as about 300 nm to about 1300 nm. The energy sources (either the energy source 274 or the heat sources 164A, 164B) may emit light at a wavelength of about 250 nm to about 1350 nm, such as about 300 nm to about 1300 nm. Other wavelengths are contemplated.

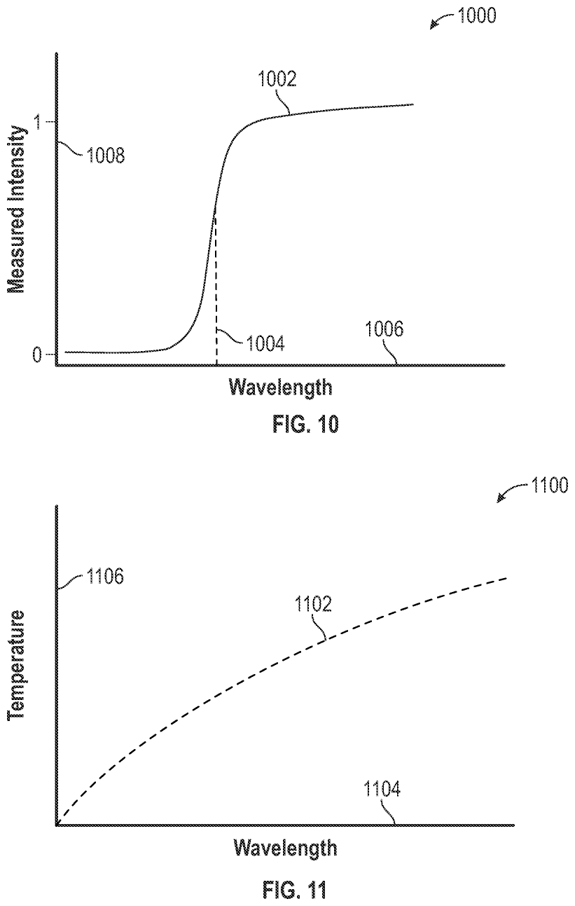

FIG. 10 shows the measurement of the intensity 1008 of wavelengths over a range of wavelengths 1006, according to one or more embodiments.

An exemplary map of the intensity of the wavelength measurements is in FIG. 10. The range of wavelengths 1006 measured by the band edge detector 276 may be the same range of wavelengths emitted by the energy source 274 as the first calibration beam 286. The intensity 1008 of the wavelengths over the range of wavelengths 1006 is mapped to form an intensity curve 1002. The intensity curve 1002 shows a sharp change between the wavelength range which is absorbed by the respective calibration substrate, the wavelength range having a low or near zero measured intensity, and the wavelength range which is reflected by the calibration substrate, the wavelength range having a high or near 1 measured intensity. The intensity is measured as a fraction of the intensity of the wavelength emitted by the energy source 274. The absorption edge wavelength is disposed in the midpoint 1004 of the transition between low measured intensity and high measured intensity of the wavelength range. The absorption edge wavelength is the wavelength at which the wavelengths transition from being absorbed to being reflected by a material. The absorption edge wavelength is directly correlated to the band gap of a material and the band gap of a material is dependent upon the temperature of the material. As temperature changes within an object, such as the calibration substrate 260A, the band gap and thus the absorption edge wavelength also changes. Therefore, a temperature of a material can be measured (e.g., a temperature reading adjusted) by measuring the absorption edge wavelength.

Returning to FIG. 9, in the third operation 906, the band edge detector 276 determines the temperature(s) of one or more (such as one, at least two, or each) of the calibration substrate(s) based off of the absorption edge wavelength(s) found in the second operation 904.

FIG. 11 shows a correlated temperature graph 1110, according to one or more embodiments. A graph such as the correlated temperature graph 1100 shown in FIG. 11 is used to equate the absorption edge wavelength with a temperature. The correlation curve 1102 of the correlated temperature graph 1100 may be found experimentally and correlates temperature 1106 to the measured absorption edge wavelength 1104. The temperature determined by the band edge detector 276 using the absorption edge wavelength is beneficial in that the determined temperature can account for inaccuracies due to the aging of any components of the process chamber, such as the process chamber 101. The absorption edge wavelength is dependent upon temperature and the material of the respective calibration substrate, and is relatively less influenced by the state of the components of the process chamber. Therefore, since the same calibration substrate(s) are used and stored between each of the calibration processes, an accurate and repeatable calibration temperature is able to be performed using the measurement assembly 270 and the band edge detector 276. The calibration temperature is the temperature measured (e.g., adjusted) by the band edge detector 276. In one or more embodiments, the calibration temperature is an actual temperature used for reference to adjust (e.g., calibrate) temperatures measured using the temperature sensor(s) (e.g., the first and second temperature sensors 272, 278 described herein).

In the fourth operation 908 the temperature(s) of one or more (such as one, at least two, or each) of the calibration substrate(s) are determined (e.g., using the first and second temperature sensors 272, 278 described herein). The temperature of the first and second temperature sensors is determined by measuring the radiation emitted by the calibration substrate(s) 260A-260E. In one or more embodiments, the temperature sensors are pyrometers. The temperature measured by the first temperature sensor is a first temperature, or a first measured temperature. The temperature measured by the second temperature sensor is a second temperature, or a second measured temperature. The areas of the calibration substrate(s) 260A-260E which are measured by the first and second temperature sensors are within about 5 mm of the radial position of the area measured by the band edge detector. In one or more embodiments, each of the first and second non-contact temperature sensors measure an area with the same radius as the area measured by the band edge detector. In one or more embodiments, the area is called a measurement point.

In one or more embodiments, the second and fourth operations 904, 908 are performed simultaneously to facilitate ensuring the temperatures measured are equivalent. In one or more embodiments, all of the first, second, third, and fourth operations 902, 904, 906, and 908 are performed simultaneously.

Over time, the temperature measurements of the first and second temperature sensors drift due to aging and wear of components of the process chamber. The temperature measurements of the non-contact temperature sensors can be calibrated periodically. In the fifth operation 910, the temperature sensors are calibrated using the calibration temperature(s) determined by the band edge detector. The temperature sensors may be adjusted to a temperature matching or near (e.g., within a predetermined degree of accuracy) the calibration temperature measured by the band edge detector. Using the adjusted temperature, a correction factor can be applied to subsequent temperature measurements taken using the temperature sensors (e.g., during epitaxial deposition processing).

In one or more embodiments, the method 900 of calibrating temperature sensors described herein is performed multiple times at a variety of temperatures so that the first and second non-contact temperature sensors may be calibrated to a wide range of temperatures. In one or more embodiments, an adjustment algorithm can determine an optimum calibration amount for the temperature sensors after the method 900 has been repeated over a range of calibration substrate temperatures and/or over a range of a plurality of calibration substrates (such as over the plurality of calibration substrates 260A-260E). The temperature sensors may be calibrated by adjusting each measurement by the same amount, or the temperature sensors may be adjusted on a curve determined by the controller 175.

The embodiments disclosed herein relate to the calibration of temperature sensors of a thermal processing chamber, such as an epitaxial processing chamber, using a band edge detector and absorption edge wavelength(s). One or more calibration substrates are used to facilitate accurate and more consistent calibration results and provide an expected absorption edge wavelength for the material of which the calibration substrate is formed.

Benefits of the present disclosure include accurate adjustment and calibration of temperature measurements; temperature measurements that account for aging and wear of chamber components; easier cleaning of chamber components; and easier transfer of calibration substrates.

It is contemplated that one or more aspects disclosed herein may be combined. As an example, one or more aspects, features, components, operations and/or properties of the processing system 100, the process chamber 101, the controller 175, the measurement assembly 270, the inner section 250, the outer section 131, one or more (such as one, at least two, or all) of the calibration substrates 260A-260E, the method 800, the method 900, the profile(s) of FIG. 10, and/or the profile(s) of FIG. 11 may be combined. Moreover, it is contemplated that one or more aspects disclosed herein may include some or all of the aforementioned benefits.

While the foregoing is directed to examples of the present disclosure, other and further examples of the disclosure may be devised without departing from the basic scope thereof, and the scope thereof is determined by the claims that follow.

What is claimed is:

1. A measurement system for measuring temperatures applicable for semiconductor manufacturing, comprising:
a substrate support assembly comprising:
an inner section comprising:
a first face,
a second face opposing the first face,
one or more first support recesses formed in the first face, and
one or more openings extending between the one or more first support recesses and the second face, and
an outer section configured to support an outer region of the inner section;
one or more calibration substrates sized and shaped for positioning at least partially in the one or more first support recesses; and
a band edge calibration assembly comprising:
an energy source positioned to emit a first energy, and
a band edge detector disposed adjacent to the energy source and positioned to receive the first energy.

2. The measurement system of claim 1, wherein the one or more calibration substrates comprise a plurality of calibration substrates, and at least two of the calibration substrates have different band gap materials.

3. The measurement system of claim 1, wherein:
the one or more calibration substrates comprise a plurality of calibration substrates; and
the plurality of calibration substrates comprise:
an inner calibration substrate having a first band gap material, and
a plurality of outer calibration substrates positioned outwardly of the inner calibration substrate and along a circumferential pattern, the plurality of outer calibration substrates comprising:
a second calibration substrate having a second band gap material,
a third calibration substrate having a third band gap material,
a fourth calibration substrate having a fourth band gap material, and
a fifth calibration substrate having a fifth band gap material.

4. The measurement system of claim 3, wherein the first band gap material includes a doped silicon.

5. The measurement system of claim 4, wherein the doped silicon is P+++ silicon or P− silicon.

6. The measurement system of claim 5, wherein:
the second band gap material includes InP;
the third band gap material includes GeN;
the fourth band gap material includes a first silicon carbide (SiC) having a first atomic structure; and
the fifth band gap material includes a second SiC having a second atomic structure.

7. The measurement system of claim 6, wherein the first atomic structure of the first SiC is 3C, and the second atomic structure of the second SiC is 4H or 6H.

8. The measurement system of claim 1, wherein the first energy is light, and the light is reflected off of at least one of the one or more calibration substrates before being received by the band edge detector.

9. The measurement system of claim 8, wherein the one or more calibration substrates comprise a plurality of calibration substrates, and the measurement system further comprises:
a first temperature sensor disposed adjacent to the band edge calibration assembly and positioned to receive a second energy; and
a controller configured to, for at least two of the plurality of calibration substrates:
emit the light toward a respective calibration substrate,
determine a band edge absorption wavelength from the light reflected off of the respective calibration substrate and received by the band edge detector,
determine a calibration temperature using the determined band edge absorption wavelength,
determine a first measured temperature based on the received second energy of the first temperature sensor, and
calibrate the first temperature sensor by comparing the first measured temperature and the calibration temperature.

10. The calibration assembly of claim 9, wherein the first temperature sensor is a pyrometer, and the second energy received by the first temperature sensor is radiation.

11. The measurement system of claim 9, further comprising a second temperature sensor disposed on an opposite side of the plurality of calibration substrates from the band edge calibration assembly and the first temperature sensor.

12. The measurement system of claim 9, wherein the band edge calibration assembly further comprises:
a collimator in optical communication with the energy source along a propagation path of the first energy;
a dichroic mirror disposed along the propagation path between the collimator and a light passage, wherein the first temperature sensor is in optical communication with the dichroic mirror along a first propagation sub-path downstream of the dichroic mirror, and the band edge detector comprises a spectrometer in optical communication with the dichroic mirror along a second propagation sub-path downstream of the dichroic mirror; and
a filter disposed along the propagation path between the energy source and the spectrometer.

13. A system for processing substrates applicable for semiconductor manufacturing, the system comprising:
a chamber body comprising one or more sidewalls, the one or more sidewalls at least partially defining an internal volume;
a lid;
a window;
one or more heat sources configured to heat the internal volume;
a substrate support assembly disposed in the internal volume, the substrate support assembly comprising:
an inner section comprising:
a first face,
a second face opposing the first face,
a plurality of first support recesses formed in the first face, and
a plurality of openings extending between the plurality of first support recesses and the second face, and
an outer section configured to support an outer region of the inner section; and
a band edge calibration assembly comprising:
an energy source positioned to emit a first energy, and
a band edge detector disposed adjacent to the energy source and positioned to receive the first energy.

14. The system of claim 13, further comprising:
a plurality of calibration substrates positioned at least partially in the plurality of first support recesses, at least two of the calibration substrates having different band gap materials.

15. The system of claim 14, further comprising:
a first temperature sensor disposed adjacent to the band edge calibration assembly and positioned to receive a second energy; and
a controller configured to, for at least two of the plurality of calibration substrates:
emit the first energy toward a respective calibration substrate,
determine a band edge absorption wavelength from the first energy reflected off of the respective calibration substrate and received by the band edge detector,
determine an calibration temperature using the determined band edge absorption wavelength,
determine a first measured temperature based on the received second energy of the first temperature sensor, and
calibrate the first temperature sensor by comparing the first measured temperature and the calibration temperature.

16. A method of calibrating measurements applicable for semiconductor manufacturing, the method comprising:
transferring a plurality of calibration substrates into a process chamber, the plurality of calibration substrates supported on a substrate support section;
irradiating the plurality of calibration substrates using an energy source;
measuring a plurality of band edge absorption wavelengths using a band edge detector;
measuring a plurality of temperatures of the calibration substrates using one or more temperature sensors;
determining a plurality of calibration temperatures of the calibration substrates using the band edge absorption wavelengths;
calibrating the one or more temperature sensors by comparing the plurality of temperatures of the calibration substrates and the plurality of calibration temperatures of the calibration substrates; and
transferring the calibration substrates supported on the substrate support section out of the process chamber.

17. The method of claim 16, further comprising performing a substrate processing operation prior to the irradiating, the substrate processing operation comprising:
heating the calibration substrates with a plurality of heat sources; and
introducing a process gas into the process chamber.

18. The method of claim 16, wherein the measuring the band edge absorption wavelengths comprises, for each of the plurality of calibration substrates, measuring an intensity of a variety of wavelengths within a wavelength spectrum of a calibration light beam incident on each of the calibration substrates.

19. The method of claim 16, wherein the calibration substrates are stored in a cassette before being transferred into the process chamber and after transferring out of the process chamber.

20. The method of claim 19, wherein after transferring the calibration substrates out of the process chamber, a plurality of substrates are processed within the process chamber.
